(19) United States
(12) Patent Application Publication
(10) Pub. No.: US 2005/0083685 A1
(43) Pub. Date: Apr. 21, 2005

(54) Illumination structure with multiple light sources and light integration device in a projection system

(76) Inventors: Hsin-Tsung Yeh, Yonghe City (TW); Rice Cheng, Gueishan Township (TW); Junejei Huang, Taoyuan Hsien (TW)

Correspondence Address: J C PATENTS, INC., 4 VENTURE, SUITE 250, IRVINE, CA, 92618, US

(21) Appl. No.: 10/965,428

(22) Filed: Oct. 12, 2004

(30) Foreign Application Priority Data
Oct. 13, 2003 (TW) 92128258

(51) Int. Cl. H01L 27/148

(52) U.S. Cl. 362/227

(57) ABSTRACT

An illumination structure with multiple light sources in projector has first, second, third integration rods, first and second light sources. The second integration rod having a light incident surface, a light outgoing surface and a light reflection surface, is placed along the first integration rod. The light incident surface is parallel to the second integration rod, forming an angle between the light incident surface and light reflection surface. The first light source is vertically placed with respect to the second light source. The light emitted from the first light source is focused to the light incident surface of the first integration rod. The light emitted from the second light source is incident to the light incident surface of the second integration rod, and then reflected by the light reflection surface. The light reflected by the light reflection surface propagates forward the light outgoing surface of the second integration rod.

### CROSS-REFERENCE TO RELATED APPLICATION

This application claims the priority benefit of Taiwan application serial no. 92128258, filed on Oct. 13, 2003.

### BACKGROUND OF THE INVENTION

1. Field of Invention

The present invention relates to an illumination structure of projection system system. More particularly, the present invention relates to a projection system with multiple light sources and light integration device.

2. Description of Related Art

The digital light processing (DLP) projection system is a projecting system designed under an almost new concept, in which the image from the DLP projection system is processed. The rather conventional digital liquid-crystal (LC) projection system is also in digital manner. However, it is done by respectively projecting three-color image signals from the red, green, and blue LC panels to being overlapping on the screen, and then the color image is displayed due to the effect of light overlapping. In the digital LC projection system, the procedure for forming the image includes the steps of analog-to-digital conversion and digital-to-analog conversion, and the final image to be projected is still in analog form. During processing several conversions of image signals between digital and analog, the distortion of image inevitably occurs.

The whole DLP projection system includes the light source, the optical splitter, the X-cube, and digital micromirror device (DMD). In the DLP projection system, in order to improve the uniformity of the light source, usually, an integration rod is implemented within the light path of the system. The light beam emitted from light source can enter into integration rod. After multiple times of total internal reflection in the integration rod, the light beam emits out from the integration rod, so as to produce the effect of uniformity. In order to improve the luminosity of the DLP projection system, one of the methods is using two light lamps for illumination. The conventional illumination structure for multiple light sources is basically in several ways as follows.

FIG. 1 is a drawing, schematically illustrating a conventional illumination structure with multiple light sources. In FIG. 1, the conventional illumination structure with multiple light sources includes light sources 11a and 11b as a lamp with parabolic lamp housing, a half cube reflector 13, a condenser lens 15 and an integration rod 17. The parallel beam emitted from the light source 11a reaches to one reflection surface of the half cube reflector 13 and is reflected to the condenser lens 15. Likewise, the parallel beam emitted from the light source 11b reaches to another reflection surface of the half cube reflector 13 and is reflected to the condenser lens 15. The parallel light beams, entering to the condenser lens 15, are condensed onto the incident surface 17a of the integration rod 17 by the condenser lens 15. After multiple times of reflection in the integration rod 17, a uniform light distribution is obtained. This illumination structure has several defects. Since the light emitted from the lamps 11a and 11b become parallel after being reflected by the lamp housing, it needs the condenser lens 15 to condense the light into the integration rod 17. Due to the use of the condenser lens 15 in the conventional illumination structure, the emitted light cannot be completely focused onto one point, and therefore the issue of spherical aberration occurs. The aberration issue causes the increase of a spot, and the efficiency for using the light source gets worse.

FIG. 2 is a drawing, schematically illustrating the second conventional illumination structure with multiple light sources. In FIG. 2, this illumination structure includes lamps 21a and 21b, a half cube reflector 23 and an integration rod 25. The 1.0 lamps 21a and 21b have elliptic housings. The light beams of the lamps 21a and 21b are reflected by the elliptic housings, which also produces focusing effect. As a result, when the light beams emitted from the lamps 21a and 21b reach to the reflection surface of the half cube reflector 23, the light beams are reflected and focused onto the incident surface 25a of the integration rod 25. In this illumination structure, since the elliptic housing of lamp has the function for focusing the light beams from the lamps, the condenser lens can be omitted and the volume of the whole structure can be reduced, and aberration issue can also be reduced. However, since the lamps 21a and 21b are in use, when the light beams 27a and 27b are in focusing, the transverse light cone angle is double from that in longitudinal direction. If it is desired for the integration rod 25 to have the same efficiency of light transmission as that of the structure in FIG. 1, the cross-sectional area of the light incident surface 25a is necessary to be reduced. However, since the cross-sectional area at the entrance of the integration rod 25 is reduced, then the light coupling efficiency is relatively reduced.

FIG. 3 is a drawing, schematically illustrating the third conventional illumination structure with multiple light sources. In FIG. 3, the illumination structure includes lamps 31a and 31b, and an integration rod 35. The lamps 31a and 31b also have the elliptic housings. In this structure, the elliptic housings of the lamps 31a and 31b in this structure are designed as the cutting corner and are disposed in a row, so as to replace the function of the half cube reflector. When lamp 31a and 31b respectively emit the light beams 33a and 33b, the light beams 33a and 33b are directly focused onto the incident surface 35a of the integration rod 35. This structure can reduce the light cone angle of the light beam 33a and 33b when focusing, so that the cross-sectional area of the integration rod increases, resulting in increase of the coupling efficiency. However, when the light beams 33a and 33b are focused, due to the reduction of the light cone angle, the cutting area of the lamps 31a and 31b becomes large, causing the lose of light beam from other place. This further causes that the light beam cannot be focused on the integration rod 35, and the light utility rate is reduced.

From the above discussions, the conventional illumination structure with multiple light sources in the projecting system has large volume incapable of reducing the volume. The aberration produced by the condenser lens structure causes worse on the whole performance. Moreover, for the foregoing conventional structure, it cannot be avoided inevitably about some disadvantages of low optical coupling efficiency and low light utility rate.

### SUMMARY OF THE INVENTION

In one aspect, the invention provides an illumination structure with multiple light sources of a projection system, which structure can have small volume, high optical coupling efficiency, and having less issue of aberration with high light utility rate.

In addition, the another aspect of the invention is to provide an illumination structure with multiple light sources of a projection system. In this structure, the lamp disposing position can be adjusted according to the different design of the projection system, and high optical coupling efficiency and high light utility rate can be maintained.

For achieving the foregoing objectives, the invention provides an illumination structure with multiple light sources in a projection system. The illumination structure with multiple light sources includes a first integration rod, a second integration rod, a third integration rod, a first light source and a second light source. Usually, the light source is the lamp. The first integration rod has a light incident surface and a light emitting surface, disposed in against relation. The second integration rod is disposed longitudinally adjacent to the first integration rod. Likewise, the second integration rod also has a light incident surface and a light emitting surface, but also has a reflection surface. The incident surface is parallel to the longitudinal direction of the second integration rod, and the reflection surface and the light incident surface form an included angle with a predetermined quantity. The third integration rod, likewise, has a light incident surface and a light emitting surface, the light incident surface of the third integration rod is coupled with each of the light emitting surface of the first integration rod and the second integration rod. The first light source and the second light source are perpendicularly disposed, so that the traveling paths of the light beams emitted from the first and the second light sources are at about 90 degrees. However, other angle is still suitable. The light beam from the first light source is focused onto the light incident surface of the first integration rod, and the light beam emitted from the second light source is incident to the light incident surface of the second integration rod. After reflection by the reflection surface of the second integration rod, the light beam travels onto the light emitting surface.

In the illumination structure with multiple light sources of the projection system, each of the light incident surfaces and the light emitting surfaces of the first the second and the third integration rods can be coated with an anti-reflection layer, and the reflection surface of the second integration rod is coated with a reflection layer. However, the light incident surface of the second integration rod can be only a portion of the longitudinal surface of the second integration rod.

In addition, each of the light emitting surfaces of the first and the second integration rods can abut to the light incident surface of the third integration rod. In this situation, a total area of each of the light emitting surfaces of the first and second integration rods can be equal to the area of the light incident surface of the third integration rod.

In the preferred condition, the included angle formed between the reflection surface and the light incident surface of the second integration rod is set to 45 degrees.

From the other aspect of the invention, the invention further provides an illumination structure with multiple light sources in a projection system, including a first integration rod, a second integration rod, a third integration rod, a first light source, and a second light source. Usually, the light sources are lamps. The first integration rod has a light incident surface, a light emitting surface, and a reflection surface, wherein the light incident surface is parallel to the longitudinal direction of the first integration rod, and a predetermined included angle is formed between the reflection surface and the light incident surface. Likewise, the second integration rod has a light incident surface, a light emitting surface, and a reflection surface, wherein the light incident surface is parallel to the longitudinal direction of the second integration rod, and a predetermined included angle is formed between the reflection surface and the light incident surface. The third integration rod has a light incident surface and a light emitting surface. Each of the light emitting surfaces of the first and the second integration rods is coupled with the light incident surface of the third integration rod. The first light source and the second light source are disposed in against relation, so that the light beams emitted from the first and the second light sources are traveling in parallel. Wherein, the light beam emitted from the first light source is incident to the first integration rod from the light incident surface, and travels toward the light emitting surface after reflection by the reflection surface of the first integration rod. The light beam emitted from the second light source is incident onto the light incident surface of the second integration rod, and then travels to the light emitting surface after reflection by the reflection surface of the second integration rod.

In the illumination structure with multiple light sources of the projection system, each of the light incident surfaces and the light emitting surfaces of the first the second and the third integration rods can be coated with an anti-reflection layer, and the reflection surfaces of the first and the second integration rods is coated with a reflection layer. However, each light incident surface of the first and the second integration rods can be only a portion of the longitudinal surface of the first and the second integration rods, respectively.

In addition, each of the light emitting surfaces of the first and the second integration rods can abut to the light incident surface of the third integration rod. In this situation, a total area of each of the light emitting surfaces of the first and second integration rods can be equal to the area of the light incident surface of the third integration rod.

In the preferred condition, the included angle formed between the reflection surface and the light incident surface of the first and the second integration rods is set to 45 degrees.

In another aspect of the invention, the invention further provides an illumination structure with multiple light sources in a projection system, including at least two integration rods, at least two light sources, and a third integration rod. Wherein, the at least two integration rods respectively have a light incident surface and a light emitting surface, in against relation. The at least two light sources relatively disposed, so that the light beams emitted from the light sources can be focused and incident onto the light incident surfaces of the integration rods. The third integration rod has a light incident surface and the light emitting surface, which are disposed so as to allow each of the light emitting surfaces coupled to the light incident surface of the third integration rod.

The invention also has another object to provide a light integration device of a projection system, including at least two integration rods and a third integration rod. Wherein, the at least two integration rods respectively have a light incident surface and a light emitting surface, in against relation. The third integration rod has a light incident surface and the light emitting surface, which are disposed so as to allow each of the light emitting surfaces coupled to the light incident surface of the third integration rod.

From the foregoing descriptions, according to the illumination structure with multiple light sources in a projection system, the light beams from the lamps, which serve as the light sources, can be directly focused onto the light incident surface of the integration rod, the condenser lens can be saved. This can reduce the volume of the projection system, but also does not produce aberration. IN addition, since the light is directly focused onto the integration rod, the light coupling rate can increase.

In addition, in the invention, the light beam is directly focused onto the integration rod. However, due to the difference of the disposing positions, the light does not be scattered in loss. The light utility rate is greatly improved. In addition, in the invention, the lamp position can be flexibly arranged according to the difference of design in outer appearance.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating one conventional illumination structure with multiple light sources.

FIG. 2 is a drawing, schematically illustrating a second conventional illumination structure with multiple light sources.

FIG. 3 is a drawing, schematically illustrating a third conventional illumination structure with multiple light sources.

FIG. 4A is a drawing, schematically illustrating an illumination structure with multiple light sources of projection system, according to a preferred embodiment of the present invention.

FIG. 4B is a drawing, schematically illustrating an illumination structure with integration rod, according to the preferred embodiment of the present invention.

FIG. 4C is a perspective view, schematically illustrating the portion of the expanded integration rod.

FIG. 5 is a drawing, schematically illustrating the optical coating on each surface of the integration rod, according to a preferred embodiment of the present invention.

FIG. 6A is a drawing, schematically illustrating an illumination structure with multiple light sources of projection system, according to another preferred embodiment of the present invention.

FIG. 6B is a drawing, schematically illustrating an illumination structure with the magnified integration rod, according to the preferred embodiment of the present invention.

FIG. 7 is a drawing, schematically illustrating optical coating process on each surface of the integration rod, according to the preferred embodiment of the present invention.

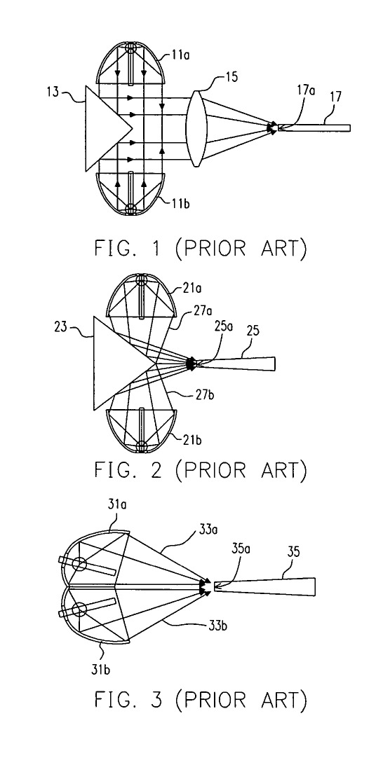

### DESCRIPTION OF THE PREFERRED EMBODIMENTS

The illumination structure with multiple light sources of a projection system in the invention mainly uses three integration rods in place of the conventional design with one integration rod. The advantage is that the light beams emitted from the lamps can be directly focused onto the integrations rod and it is not necessary to have the cutting-angle design on the lamp housing. The light beam emitted from each lamp can pass an integration rod, and then further collected by the third integration rod. After the total internal reflections for getting uniform, the light beams are led out from the integration rod. In the following embodiment, the longitudinal direction is defined as the direction of the longer optical axis of the integration rod, that is, the traveling direction of the light in the integration rod.

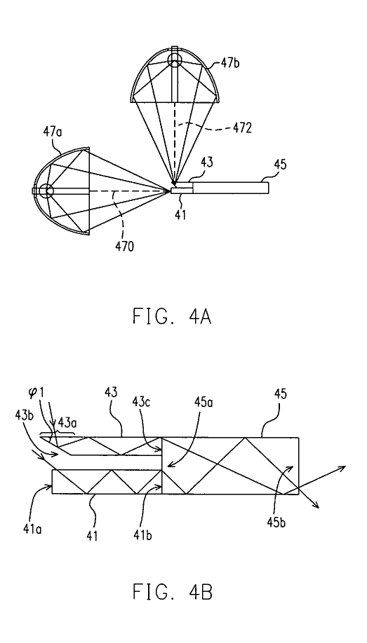

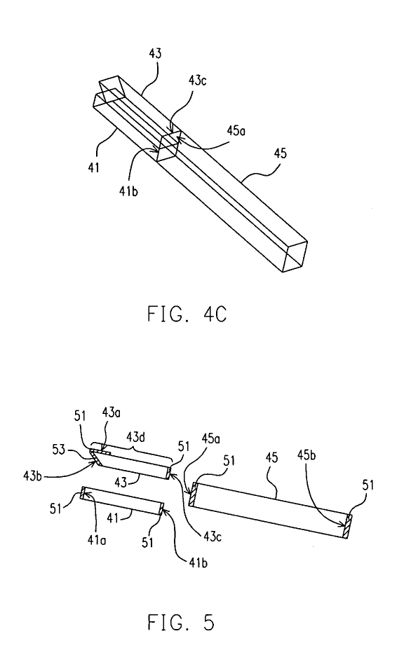

FIG. 4A is a drawing, schematically illustrating an illumination structure with multiple light sources of projection system, according to a preferred embodiment of the present invention. FIG. 4B is a drawing, schematically illustrating an illumination structure with integration rod, according to the preferred embodiment of the present invention. FIG. 4C is a perspective view, schematically illustrating the portion of the expanded integration rod. In FIG. 4A to FIG. 4C, the invention provides an illumination structure with multiple light sources of projection system, including a first integration rod 41, a second integration rod 43, a third integration rod 45, and a first lamp 47a with a second lamp 47b, serving as the light source. The integration rods can be, for example, glass bodies. The first integration rod 41 has the light incident surface 41a and the light emitting surface 41b. The light incident surface 41a and the light emitting surface 41b are opposite to each other, and are disposed in parallel. The second integration rod 43 similarly has the light incident surface 43a and the light emitting surface 43c, and the second integration rod 43 further has the reflection surface 43b. Likewise, the light incident surface 43a and the light emitting surface 43c are against to each other, and are disposed in parallel. The light incident surface 43a is parallel to the longitudinal direction of the second integration rod 43. The reflection surface 43b and the light incident surface 43a includes a predetermined angle φ1, so that the integration rod 41 has the trapezoid shape at the cross-sectional view. The predetermined angle φ1 is designed for allowing the light beam emitted from the second lamp 47b to be incident to the second integration rod 43, and then reflected at the reflection surface 43b so as to longitudinally travel forward in the second integration rod. As a result, under the foregoing structure, when the light of the second lamp 47b is incident about perpendicular to the light incident surface 43a, the predetermined angle φ1, included between the reflection surface 43b and the light incident surface 43a of the second integration rod 43 is preferably set to be 45 degrees. Alternatively, the angle φ1 can be adjusted according to the location of the second lamp 47b.

The longitudinal side of the integration rod 43 is parallel to the longitudinal side of the first integration rod 41, and the second integration rod 43 is abutting to the first integration rod 41 in the longitudinal direction. The third integration rod 45 also has the light incident surface 45a and the light emitting surface 45b, wherein the light incident surface 45a and the light emitting surface 45b are arranged in a way like the first integration rod 41. The light emitting surface 41b of the first integration rod 41 and the light emitting surface 43c of the second integration rod 43 are coupled to the light incident surface 45a of the third integration rod 45. The light emitting surfaces 41b and 43c are abutting to the light incident surface 45a. In the embodiment, the lamp housings, such as elliptic lamp housing, of the first lamp 47a and the second lamp 47b have the function for focusing the light beam. As shown in FIG. 4A, the axes 470, 472 of the first lamp 47a and the second lamp 47b are perpendicular to each other, so that the light paths of the emitted light beams are traveling by 90 degrees. However, other implementation angle can also be used.

As shown in FIG. 4C, preferably in the embodiment, the light emitting surface 41b of the first integration rod 41 and the light emitting surface 43c of the integration rod 43 are abutting to the light incident surface 45a of the third integration rod 45. In addition, the total area of the light emitting surface 41b of the first integration rod 41 and the light emitting surface 43c of the integration rod 43 is equal to the area of the light incident surface 45a of the third integration rod 45.

Still referring to FIG. 4B, the light traveling path is described. The light beam emitted from the first lamp 47a is focused by elliptic lamp housing and incident to the light incident surface 41a of the first integration rod 41. The incident light beam has multiple times of total internal reflection in the integration rod 41, and then uniformly emits out from the light emitting surface 41b. The light beam emitted from the light emitting surface 41b is incident to the third integration rod 45 at the light incident surface 45a. Moreover, the light beam emitted from the second lamp 47b is focused by elliptic lamp housing and incident to the light incident surface 43a of the second integration rod 43. The incident light beam is reflected by the reflection surface 43b in the second integration rod 43, and then travels toward the light emitting surface 43c. After multiple times of total internal reflection, the light beam uniformly emits out from the light emitting surface 43c. The light beam emitted from the light emitting surface 43c is incident to the third integration rod 45 at the light incident surface 45a. After the light beam in incident to the third integration rod 45, likewise, the light beam is internally reflected by multiple times, and then emits at the light emitting surface 45b.

In order to more effectively achieve the above objectives, the invention further processes the light incident surface, the light emitting surface, and the reflection surface of the integration rod. FIG. 5 is a drawing, schematically illustrating the optical coating on each surface of the integration rod, according to a preferred embodiment of the present invention. Referring to FIGS. 4A, 4B and 5, in the embodiment, usually, when the light beam is incident into a medium from the light incident surface, a portion of the light is inevitably reflected at the incident surface, and cannot cause all of the light beam to enter the medium. Likewise, in order to allow the light incident to be more efficient in the structure of the invention, the light incident surface is processed by an optical coating film. For example, the light incident surface 41a and the light emitting surface 41b of the first integration rod 41, the light incident surface 43a and the light emitting surface 43c of the second integration rod 43 and the light incident surface 45a and the light emitting surface 45b of the third integration rod 45 are coated with an anti-reflection layer 51, so that when the light beams are incident to the surfaces, the utility rate of the light beam is not reduced during the reflection. Also and, the reflection surface 43b of the second integration rod 43 is coated with a reflection layer 53, so that when the light beam is incident to the reflection surface, it can be almost reflected without transmission. As a result, this can prevent the light loss from occurring, causing the reduction of the utility rate. Here, the light incident surface 43a of the second integration rod 43 is only a portion of the longitudinal surface 43d of the second integration rod 43.

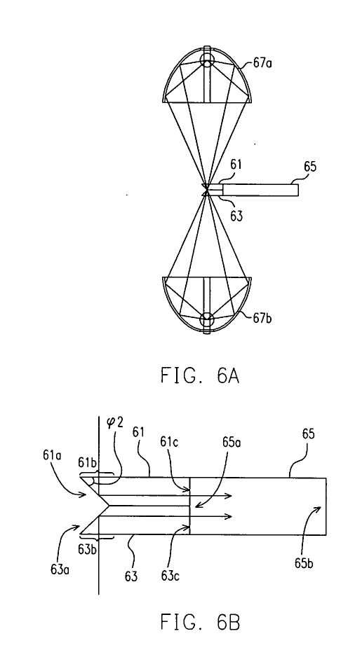

FIG. 6A is a drawing, schematically illustrating an illumination structure with multiple light sources of projection system, according to another preferred embodiment of the present invention. FIG. 6B is a drawing, schematically illustrating an illumination structure with the magnified integration rod, according to the preferred embodiment of the present invention. In FIG. 6A and FIG. 6B, the difference of this embodiment from the previous embodiment is the disposed positions of the first lamp 67a and the second lamp 67b. In this embodiment, the first lamp 67a and the second lamp 67b are disposed in against manner, so that the light beams emitted from the first lamp 67a and the second lamp 67b are traveling in parallel and against. In addition, the two lamps 67a, 67b are perpendicularly incident to the longitudinal side surface of the integration rods. Comparing with the first integration rod 41 of the previous embodiment, since the first lamp 67a is disposed at the different position, the first integration rod 61 has also been modified. As shown in FIG. 6B, the integration rod 61 of this embodiment also has a light incident surface 61b and a light emitting surface 61c. However, since the light beam emitted from the first lamp 67a is perpendicular to the longitudinal side surface of the first integration rod 61, the light incident surface 61b is arranged to be parallel to the longitudinal side surface of the first integration rod 61. Here, the end surface abutting to the light incident surface 61b of the first integration rod 61 (perpendicular to the longitudinal side surface) is cut in tilt by a predetermined angle φ2, so that the inner side of the tilt cutting surface of the integration rod 61 is used as the reflection surface 61a. In other words, the reflection surface 61a and the incident surface 61b include a predetermined angle φ2. With the function of the reflection surface 43b of the second integration rod 43 in previous embodiment, the reflection surface 61a is used to allow the light beam, which is emitted from the first lamp 67a and is incident to the light incident surface 61b, to travel toward the light emitting surface 61c after being reflected by the reflection surface 61a. In this structure, when the light beam of the first lamp 67a is about perpendicularly incident to the ling incident surface 61b, the predetermined angle φ2, which is included between the reflection surface 61a and the light incident surface 61b of the first integration rod 61, is preferably set to be 45 degrees. In addition, since the way of disposing positions of the second lamp 67b and the second integration rod 63 are similar to the first lamp 67a and the first integration rod 61, the reflection surface 63a and the light incident surface 63b of the second integration rod 63 also include a predetermined angle φ2, like that in the first integration rod 61. This predetermined angle φ2 is also preferably set to be 45 degrees. The function of the second integration rod 63 in the embodiment is similar to the second integration rod 43 in previous embodiment, and is not repeatedly described.

Still referring to FIG. 6B about the light traveling path, in the embodiment, the traveling path of the light beam from the second lamp 67b is similar to the traveling path from the second lamp 47b in the previous embodiment, referring to previous embodiment. The light beam emitted from the first lamp 67a is incident to the light incident surface 61b of the first integration rod 61, and travels toward the light emitting surface 63c after being reflected by the reflection surface 61a of the first integration rod 61. After multiple times of total internal reflection in the first integration rod 61, the light beam is uniformly emitted from the light emitting surface 61c and immediately enters the third integration rod 65 from the light incident surface 65a. Likewise, the light beam in the third integration rod 65 has multiple times of total internal reflection and then is uniformly emitted from the light emitting surface 65b.

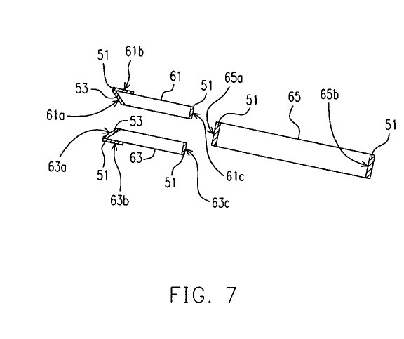

FIG. 7 is a drawing, schematically illustrating optical coating on each surface of the integration rod, according to the preferred embodiment of the present invention. In FIG. 5A, FIG. 5B, and FIG. 7, with the similar reasons in previous embodiment, the surfaces of the integrations rod have been processed with optical coating films. In this embodiment, the process of optical coating films on the second and the third integration rod are similar to that in FIG. 5A, without repeated description. However, the surface coating process on the surfaces of the first integration rod 61 is looked into. The light incident surface 61b and the light emitting surface 61c of the integration rod 61 are coated with anti-reflection layer 51, so that when the light is incident on the surfaces, the utility rate of the light beam is not reduced caused by the light reflection. Also and, the light emitting surface 61a is coated with a reflection layer 52, so that when the light beam is incident to the reflection surface 61a, the light beam can be almost all reflected without transmission. This can prevent the light loss from occurring, causing the low utility rate of the light beam. Likewise, the light incident surface of the first integration rod 61 is only a portion of the longitudinal side surface 63d of the first integration rod 63.

In summary, according to the illumination structure with multiple light sources in the invention, since each lamp is with respect to an integration rod, the light cone angle of each lamp can maintain the same effect as that with the structure in single lamp. In addition, according to Etendue optical design theory, the product of the light cone angle and the cross-sectional area of the integration rod is a constant. In this manner, the cross-sectional area of the structure of the invention is not reduced. In other words, the cross-sectional area is not reduced, the light coupling ratio is not reduced either.

Even though the forgoing embodiments use the example for descriptions, implemented by the first integration rod, the second integration rod, the first lamp, and the second lamp, the invention is not limited to this implementation. The implementation manner is not necessary to be limited in the structure elements.

That is, according to the structure of the invention, the end surface of the integration (perpendicular to the longitudinal direction) is designed according to the lamp position. For example, when the light beam from the lamp is focused and is incident to the end surface of the integration rod, the end surface is not necessary to be processed with tilt cutting. In this situation, it has been sufficient to coat the anti-reflection layer thereon. In addition, if the light beam from the lamp is perpendicularly incident to the integration rod from the longitudinal side surface, then the end surface adjacent to the light incident surface is cut by a predetermined tilt angle, so as to allow the light beam to be reflected, as foregoing descriptions, and longitudinally travels along the integration rod. Therefore, in the design principle, no matter how to implement any number of the lamps and the integration rod at any positions, any design at the end satisfies the forgoing design principle is the feature of the invention.

When it has a plurality of lamps (assuming to have N lamps), according to the design principle of the invention, it needs no more than N+1 of integration rods. N of the integration rods are with respect to the number of the light sources one to one, and the additional one of the integration rods is used to collect the light beams from the N of integration rods. As to which one of the integration rods is to be cut at the end surface, it is then depending on the positions of the lamps.

From the foregoing embodiments, the illumination structure with multiple light sources in a projection system of the invention, if the lamp housing of the lamp is, for example, the elliptic lamp housing, it automatically has the focusing function when the light beam is reflected. Therefore, it needs not to use the condenser lens and the half cube reflector without causing the aberration issue, so that the volume can be reduced. In addition, since the light beam from the light source provided by the invention is directly focused on the integration rod, the light cone angle can be reduced.

Even though the light source provided by the invention is directly focused on the integration rod, the light source of the invention needs no the cutting corner. Instead, it is achieved by disposing at different positions. This not only causes the light beam be not easy in scattering loss, so as to increase the utility rate of the light, but also allows the implementing positions of the light sources to be freely adjusted, according to the different design of the projecting system.

It will be apparent to those skilled in the art that various modifications and variations can be made to the illumination structure of the present invention without departing from the scope or spirit of the invention. In view of the foregoing descriptions, it is intended that the present invention covers modifications and variations of this invention if they fall within the scope of the following claims and their equivalents.

1. An illumination structure with multiple light sources in a projection system, comprising:
a first integration rod, having a light incident surface and a light emitting surface in an opposite relation;
a second integration rod, abutting to the first integration rod, having a light incident surface, a light emitting surface and a reflection surface; and
a third integration rod, having a light incident surface and a light emitting surface, disposed to couple with the light emitting surfaces of the first and second integration rods;
wherein the light sources are disposed, so that light beams can be emitted to the light incident surface of the first and second integration rods.

2. The illumination structure of claim 1, wherein each of the light incident surfaces and the light emitting surfaces of the first, the second, and the third integration rods are coated with an anti-reflection layer, and the reflection surface of the second integration rod is coated with a reflection layer.

3. The illumination structure of claim 2, wherein the light incident surface of the second integration rod is only a portion of a longitudinal surface of the second integration rod.

4. The illumination structure of claim 1, wherein the light emitting surfaces of the first and the second integration rods are abutting to the light incident surface of the third integration rod.

5. The illumination structure of claim 1, wherein a total area of the light incident surfaces of the first and the second integration rods is equal to an area of the light incident surface of the third integration rod.

6. An illumination structure with multiple light sources in a projection system, comprising:
a first integration rod, having a light incident surface and a light emitting surface in against relation;
a second integration rod, longitudinally abutting to the first integration rod, having a light incident surface, a light emitting surface, and a reflection surface, wherein the light incident surface is parallel to a longitudinal direction of the second integration rod, wherein after a light beam being incident to the second integration rod is reflected by the reflection surface, the light beam travels along a longitudinal direction of the second integration rod; and
a third integration rod, having a light incident surface and a light emitting surface, disposed at a position to couple with the light emitting surfaces of the first and the second integration rods.

7. The illumination structure of claim 6, wherein each of the light incident surfaces and the light emitting surfaces of the first, the second, and the third integration rods are coated with an anti-reflection layer, and the reflection surface of the second integration rod is coated with a reflection layer.

8. The illumination structure of claim 7, wherein the light incident surface of the second integration rod is only a portion of a longitudinal surface of the second integration rod.

9. The illumination structure of claim 6, wherein the light emitting surfaces of the first and the second integration rods are abutting to the light incident surface of the third integration rod.

10. The illumination structure of claim 6, wherein a total area of the light incident surfaces of the first and the second integration rods is equal to an area of the light incident surface of the third integration rod.

11. An illumination structure with multiple light sources in a projection system, comprising:
a first integration rod, having a light incident surface, a light emitting surface, and a reflection surface, wherein the light incident surface is parallel to a longitudinal direction of the first integration rod;
a second integration rod, longitudinally abutting to the first integration rod, having a light incident surface, a light emitting surface, and a reflection surface, wherein the light incident surface is parallel to a longitudinal direction of the second integration rod;
a third integration rod, having a light incident surface and a light emitting surface, disposed at a position to allow each of the light emitting surfaces of the first and second integration rods to be coupled with the light incident surface of the third integration rod; and
a first light source with a second light source, which are disposed so as to allow light beams emitted from the first light source and the second light source are traveling in parallel to each other,
wherein the light beam emitted from the first light source is about perpendicular to the light incident surface of the first integration rod, and travels toward the light emitting surface after being reflected by the reflection surface of the first integration rod, wherein the light beam emitted from the second light source is about perpendicular to the light incident surface of the second integration rod, and travels toward the light emitting surface after being reflected by the reflection surface of the second integration rod.

12. The illumination structure of claim 11, wherein each of the light incident surfaces and the light emitting surfaces of the first, the second, and the third integration rods are coated with an anti-reflection layer, and each of the reflection surfaces of the first and the second integration rods is coated with a reflection layer.

13. The illumination structure of claim 12, wherein the light incident surfaces of the first and the second integration rods are respectively only a portion of longitudinal surfaces of the first and the second integration rod.

14. The illumination structure of claim 12, wherein the light emitting surfaces of the first and the second integration rods are abutting to the light incident surface of the third integration rod.

15. The illumination structure of claim 12, wherein a total area of the light incident surfaces of the first and the second integration rods is equal to an area of the light incident surface of the third integration rod.

16. An illumination structure with multiple light sources in a projection system, comprising:
a first integration rod, having a light incident surface, a light emitting surface, and a reflection surface, wherein the light incident surface is parallel to a longitudinal direction of the first integration rod, wherein after a light beam being incident to the first integration rod is reflected by the reflection surface, the light beam travels along a longitudinal direction of the second integration rod;
a second integration rod, longitudinally abutting to the first integration rod, having a light incident surface, a light emitting surface, and a reflection surface, wherein the light incident surface is parallel to a longitudinal direction of the second integration rod, after a light beam being incident to the second integration rod is reflected by the reflection surface, the light beam travels along a longitudinal direction of the second integration rod; and
a third integration rod, having a light incident surface and a light emitting surface, disposed at a position to allow each of the light emitting surfaces of the first and the second integration rods to be coupled with the light incident surface of the third integration rod.

17. The illumination structure of claim 16, wherein each of the light incident surfaces and the light emitting surfaces of the first, the second, and the third integration rods are coated with an anti-reflection layer, and each of the reflection surfaces of the first and the second integration rods is coated with a reflection layer.

18. The illumination structure of claim 16, wherein the light incident surfaces of the first and the second integration rods are respectively only a portion of longitudinal surfaces of the first and the second integration rod.

19. The illumination structure of claim 16, wherein the light emitting surfaces of the first and the second integration rods are abutting to the light incident surface of the third integration rod.

20. The illumination structure of claim 16, wherein a total area of the light incident surfaces of the first and the second integration rods is equal to an area of the light incident surface of the third integration rod.

21. An illumination structure with multiple light sources in a projection system, comprising:
at least two integration rods, each of which has a light incident surface and a light emitting surface in against relation;
a third integration rod, having a light incident surface and a light emitting surface, which are disposed so as to allow each of the light emitting surfaces to be coupled to the light incident surface of the third integration rod; and
at least two light sources, disposed in against relation, so that light beams emitted from the light sources are respectively focused onto the light incident surface of the integrations rods.

22. The illumination structure of claim 21, wherein each of the light incident surface and the light emitting surfaces of the at least two integration rods and the third integration rod is coated with an anti-reflection layer.

23. An illumination structure with multiple light sources in a projection system, comprising:
at least two integration rods, each of which has a light incident surface and a light emitting surface in against relation; and
a third integration rod, having a light incident surface and a light emitting surface, which are disposed so as to allow each of the light emitting surfaces to be coupled to the light incident surface of the third integration rod
